(19) United States
(12) Patent Application Publication
(10) Pub. No.: US 2026/0072088 A1
(43) Pub. Date: Mar. 12, 2026

(54) VISUALIZATION OF BATTERY CHARGING HISTORY AND STATE OF HEALTH

(71) Applicant: TOYOTA RESEARCH INSTITUTE, INC., Los Altos, CA (US)

(72) Inventors: David Ayman SHAMMA, Mountain View, CA (US); Alexandre Leo Stephen FILIPOWICZ, Mountain View, CA (US)

(73) Assignees: TOYOTA RESEARCH INSTITUTE, INC., Los Altos, CA (US); TOYOTA JIDOSHA KABUSHIKI KAISHA, Aichi-Ken (JP)

(21) Appl. No.: 18/830,441

(22) Filed: Sep. 10, 2024

(51) Int. Cl. G01R 31/371; G01R 31/367; G01R 31/382; G01R 31/392

(52) U.S. Cl. CPC G01R 31/371; G01R 31/367; G01R 31/382; G01R 31/392

(57) ABSTRACT

A method for visualizing health of a re-chargeable battery includes collecting, over a period of time, charging event data including charging type and charging duration. The method also includes determining an estimated battery degradation based on the charging event data, the estimated battery degradation accounting for normal battery degradation. The method further includes generating a visual representation of the charging event data and the estimated battery degradation. The method also includes displaying the visual representation via an in-car display

### BACKGROUND

### Field

Certain aspects of the present disclosure generally relate to battery charging, and more specifically to systems and methods for visualization of battery charging history and state of health.

### Background

Battery health refers to the overall condition and performance capability of a battery, particularly in terms of its ability to store and deliver electrical energy efficiently over time. For electric vehicles (EVs), battery health may affect the EV's range, performance, and longevity. Several factors influence battery health, including capacity retention, which measures how much charge the battery can hold compared to its original capacity when new. Over time, a battery's capacity diminishes due to factors, such as, but not limited to, chemical reactions within the cells, usage patterns, and cycle life. Cycle life refers to a number of complete charge and discharge cycles a battery can undergo before its capacity significantly drops, with a higher cycle life indicating a longer-lasting battery.

State of Charge (SoC) represents a current charge level of the battery as a percentage of its total capacity, and maintaining an optimal SoC range can prolong battery life. Depth of Discharge (DoD) refers to how much of the battery's capacity is used during a discharge cycle, with shallow discharges generally being better for battery health compared to deep discharges. Temperature also plays a role in battery health, as batteries perform optimally within a certain temperature range, and extreme temperatures can accelerate degradation and reduce battery health. Additionally, charging patterns, such as the type of charging (fast vs. slow) and frequency, can impact battery health, with frequent fast charging leading to quicker degradation.

Good battery health ensures that the EV can travel its maximum possible range on a single charge, while deteriorating battery health decreases the EV's range. Maintaining battery health helps extend the overall lifespan of the battery, reducing the frequency and cost of replacements. Poor battery health can increase the risk of issues such as overheating. The condition of the battery may affect the resale value of an EV, with a well-maintained battery being more attractive to potential buyers.

### SUMMARY

In some aspects of the present disclosure, a method for visualizing health of a re-chargeable battery associated with a vehicle includes collecting, over a period of time, charging event data including charging type and charging duration. The method also includes determining an estimated battery degradation based on the charging event data, the estimated battery degradation accounting for normal battery degradation. The method further includes generating a visual representation of the charging event data and the estimated battery degradation. The method still further includes displaying the visual representation via an in-car display of the vehicle.

Other aspects of the present disclosure are directed to an apparatus. The apparatus includes means for collecting, over a period of time, charging event data including charging type and charging duration. The apparatus also includes means for determining an estimated battery degradation based on the charging event data, the estimated battery degradation accounting for normal battery degradation. The apparatus further includes means for generating a visual representation of the charging event data and the estimated battery degradation. The apparatus still further includes means for displaying the visual representation via an in-car display of the vehicle.

In other aspects of the present disclosure, a non-transitory computer-readable medium with program code recorded thereon is disclosed. The program code is executed by a processor and includes program code to collect, over a period of time, charging event data including charging type and charging duration. The program code further includes program code to determine an estimated battery degradation based on the charging event data, the estimated battery degradation accounting for normal battery degradation. The program code also includes program code to generate a visual representation of the charging event data and the estimated battery degradation. The program code still further includes program code to display the visual representation via an in-car display of the vehicle.

Other aspects of the present disclosure are directed to apparatus for visualizing health of a re-chargeable battery associated with a vehicle, comprising one or more processors; and one or more memories coupled with the one or more processors and storing processor-executable code that, when executed by the one or more processors, is configured to cause the apparatus to collect, over a period of time, charging event data including charging type and charging duration. Execution of the processor-executable coder also causes the apparatus to determine an estimated battery degradation based on the charging event data, the estimated battery degradation accounting for normal battery degradation. Execution of the processor-executable coder further causes the apparatus to generate a visual representation of the charging event data and the estimated battery degradation. Execution of the processor-executable coder still further causes the apparatus to display the visual representation via an in-car display of the vehicle.

Aspects generally include a method, apparatus, system, computer program product, non-transitory computer-readable medium, user equipment, base station, wireless communication device, and processing system as substantially described with reference to and as illustrated by the accompanying drawings and specification.

The foregoing has outlined rather broadly the features and technical advantages of examples according to the disclosure in order that the detailed description that follows may be better understood. Additional features and advantages will be described. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed, both their organization and method of operation, together with associated advantages will be better understood from the following description when considered in connection with the accompanying figures. Each of the figures is provided for the purposes of illustration and description, and not as a definition of the limits of the claims.

### BRIEF DESCRIPTION OF THE DRAWINGS

The features, nature, and advantages of the present disclosure will become more apparent from the detailed description set forth below when taken in conjunction with the drawings in which like reference characters identify correspondingly throughout.

FIG. 1A is a diagram illustrating an example of a vehicle in an environment, in accordance with various aspects of the present disclosure.

FIG. 1B is a diagram illustrating an example of the vehicle, in accordance with various aspects of the present disclosure.

FIG. 2 is a block diagram illustrating a software architecture that may modularize artificial intelligence (AI) functions for planning and control of an autonomous agent, in accordance with various aspects of the present disclosure.

FIG. 3 is a diagram illustrating an example of a hardware implementation for a vehicle control system, in accordance with various aspects of the present disclosure.

FIGS. 4, 5, 6, and 7A are diagrams illustrating examples of a visualization, in accordance with various aspects of the present disclosure.

FIG. 7B is an example of the visualization with an adjusted granularity, in accordance with various aspects of the present disclosure.

FIG. 8 is an example of the visualization with an adjusted granularity, in accordance with various aspects of the present disclosure.

FIGS. 9, 10, and 11 are diagrams illustrating examples of a visualization 900 showing a predicted degradation, in accordance with various aspects of the present disclosure.

FIGS. 12A and 12B are diagram illustrating an in-car display unit displaying a visualization, in accordance with various aspects of the present disclosure.

FIG. 13 illustrates a flow diagram for a process for generating and displaying a visualization associated with battery health, in accordance with various aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts.

Several aspects of battery systems and other vehicle systems will now be presented with reference to various apparatuses and techniques. These apparatuses and techniques will be described in the following detailed description and illustrated in the accompanying drawings by various blocks, modules, components, circuits, steps, processes, algorithms, and/or the like (collectively referred to as “elements”). These elements may be implemented using hardware, software, or combinations thereof. Whether such elements are implemented as hardware or software depends upon the particular application and design constraints imposed on the overall system.

As discussed, battery health refers to the overall condition and performance capability of a battery, particularly in terms of its ability to store and deliver electrical energy efficiently over time. For electric vehicles (EVs), battery health may affect the EV's range, performance, and longevity. Several factors influence battery health, including capacity retention, which measures how much charge the battery can hold compared to its original capacity when new. Over time, a battery's capacity diminishes due to factors, such as, but not limited to, chemical reactions within the cells, usage patterns, and cycle life. Cycle life refers to a number of complete charge and discharge cycles a battery can undergo before its capacity significantly drops, with a higher cycle life indicating a longer-lasting battery.

State of Charge (SoC) represents a current charge level of the battery as a percentage of its total capacity, and maintaining an optimal SoC range can prolong battery life. Depth of Discharge (DoD) refers to how much of the battery's capacity is used during a discharge cycle, with shallow discharges generally being better for battery health compared to deep discharges. Temperature also plays a role in battery health, as batteries perform optimally within a certain temperature range, and extreme temperatures can accelerate degradation and reduce battery health. Additionally, charging patterns, such as the type of charging (fast vs. slow) and frequency, can impact battery health, with frequent fast charging leading to quicker degradation.

Good battery health ensures that the EV can travel its maximum possible range on a single charge, while deteriorating battery health decreases the EV's range. Maintaining battery health helps extend the overall lifespan of the battery, reducing the frequency and cost of replacements. Poor battery health can increase the risk of issues such as overheating. The condition of the battery may affect the resale value of an EV, with a well-maintained battery being more attractive to potential buyers.

Based on U.S. regulations, vehicles, such as EVs, may be mandated to display battery health information. These regulations specify that drivers should have access to an instant readout of the percent of mileage loss due to battery degradation. However, this approach has several potential drawbacks. Firstly, the percentage of battery degradation may not be easily understood by drivers, leaving drivers unclear about the health of their battery. Secondly, in most cases, the observed loss (approximately 2% per year) is a normal occurrence and not necessarily a cause for concern. Lastly, the percent of mileage loss due to battery degradation does not provide drivers with insights into better charging behaviors or highlight the specific charging history that might have contributed to the battery's condition.

To address these issues, various aspects of the present disclosure are directed to generating a visualization that presents a detailed history of different types of charging activities that can impact the battery's health over time. The visualization may be referred to as a battery flag. Furthermore, the visualization may provide a more comprehensive view of the battery's condition beyond the mere percentage of degradation. In some examples, the visualization illustrates overall charging habits and how these habits could lead to service issues or indicate that the battery has been well maintained. By displaying a normalized area chart, the visualization improves a user's understanding of their charging behaviors and how the charging behaviors affect battery health. The charging behavior may indicate a type of charger that was used, such as fast charging, level one (L1), or level two (L2). The charging behavior may also be referred to as a charging pattern. Providing a visualization of the charging behavior helps inform drivers of the best practices for maintaining battery health and allows drivers to make more informed decisions regarding their charging habits and overall vehicle maintenance.

In some examples, to generate the visualization, an EV may be equipped with systems that continuously monitor various parameters affecting battery health, including SoC, temperature, and charging behavior. Educating users about optimal charging practices and the impacts of different driving behaviors on battery health can help prolong battery life. Visual tools, such as battery flags, can help drivers understand their battery health better and make informed decisions about their vehicle usage. Battery health is a critical aspect of EV maintenance that affects performance, safety, and cost-efficiency. Providing a visualization to help drivers better understand and monitor the factors that influence battery health may increase the lifespan and efficiency of EV batteries.

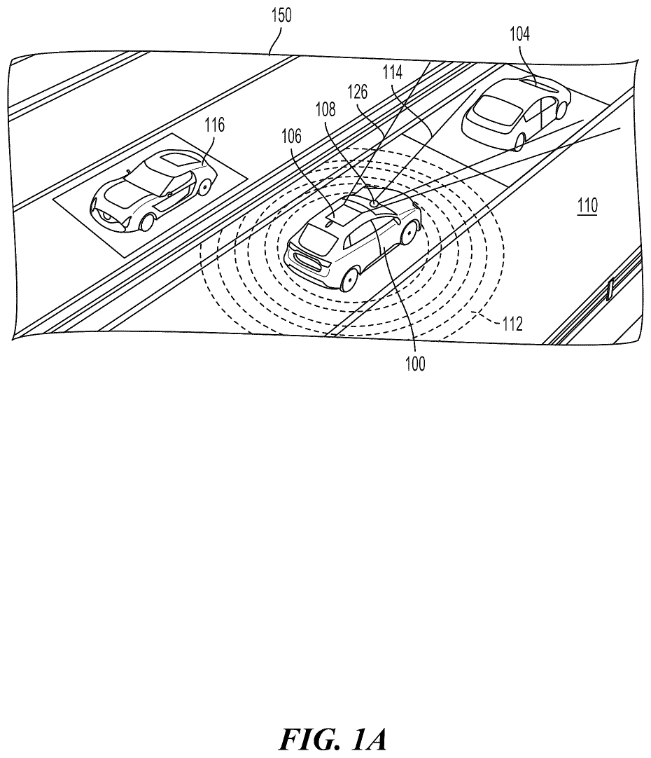

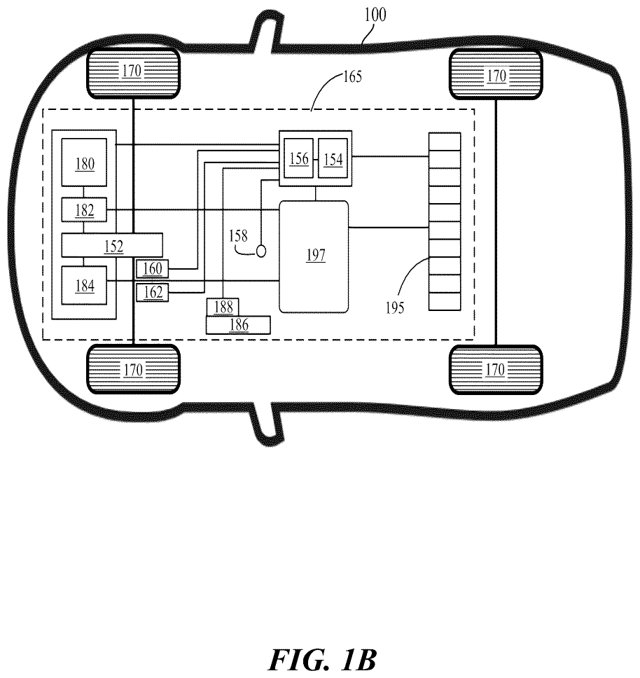

FIG. 1A is a diagram illustrating an example of a vehicle 100 in an environment 150, in accordance with various aspects of the present disclosure. In the example of FIG. 1A, the vehicle 100 may be an autonomous vehicle, a semi-autonomous vehicle, or a non-autonomous vehicle. As shown in FIG. 1A, the vehicle 100 may be traveling on a road 110. A first vehicle 104 may be ahead of the vehicle 100 and a second vehicle 116 may be adjacent to the ego vehicle 100. In this example, the vehicle 100 may include a 2D camera 108, such as a 2D red-green-blue (RGB) camera, and a LIDAR sensor 106. Other sensors, such as RADAR and/or ultrasound, are also contemplated. Additionally, or alternatively, although not shown in FIG. 1A, the vehicle 100 may include one or more additional sensors, such as a camera, a RADAR sensor, and/or a LIDAR sensor, integrated with the vehicle in one or more locations, such as within one or more storage locations (e.g., a trunk). Additionally, or alternatively, although not shown in FIG. 1A, the vehicle 100 may include one or more force measuring sensors.

In one configuration, the 2D camera 108 captures a 2D image that includes objects in the 2D camera's 108 field of view 114. The LIDAR sensor 106 may generate one or more output streams. The first output stream may include a 3D cloud point of objects in a first field of view, such as a 360°field of view 112 (e.g., bird's eye view). The second output stream 124 may include a 3D cloud point of objects in a second field of view, such as a forward facing field of view 126.

The 2D image captured by the 2D camera includes a 2D image of the first vehicle 104, as the first vehicle 104 is in the 2D camera's 108 field of view 114. As is known to those of skill in the art, a LIDAR sensor 106 uses laser light to sense the shape, size, and position of objects in the environment 150. The LIDAR sensor 106 may vertically and horizontally scan the environment 150. In the current example, the artificial neural network (e.g., autonomous driving system) of the vehicle 100 may extract height and/or depth features from the first output stream. In some examples, an autonomous driving system of the vehicle 100 may also extract height and/or depth features from the second output stream.

The information obtained from the sensors 106, 108 may be used to evaluate a driving environment. Additionally, or alternatively, information obtained from one or more sensors that monitor objects within the vehicle 100 and/or forces generated by the vehicle 100 may be used to generate notifications when an object may be damaged based on actual, or potential, movement.

FIG. 1B is a diagram illustrating an example the vehicle 100, in accordance with various aspects of the present disclosure. It should be understood that various aspects of the present disclosure may be applicable to/used in various vehicles (internal combustion engine (ICE) vehicles with one or more rechargeable batteries, fully electric vehicles (EVs), and/or other types of vehicles with one or more rechargeable batteries.) that are fully or partially autonomously controlled/operated, and as noted above, even in non-vehicular contexts, such as, e.g., shipping container packing.

The vehicle 100 may include drive force unit 165 and wheels 170. The drive force unit 165 may include an engine 180, motor generators (MGs) 182 and 184, a battery 195, an inverter 197, a brake pedal 186, a brake pedal sensor 188, a transmission 152, a memory 154, an electronic control unit (ECU) 156, a shifter 158, a speed sensor 160, and an accelerometer 162.

The engine 180 primarily drives the wheels 170. The engine 180 can be an ICE that combusts fuel, such as gasoline, ethanol, diesel, biofuel, or other types of fuels which are suitable for combustion. The torque output by the engine 180 is received by the transmission 152. MGs 182 and 184 can also output torque to the transmission 152. The engine 180 and MGs 182 and 184 may be coupled through a planetary gear (not shown in FIG. 1B). The transmission 152 delivers an applied torque to one or more of the wheels 170. The torque output by engine 180 does not directly translate into the applied torque to the one or more wheels 170.

MGs 182 and 184 can serve as motors which output torque in a drive mode, and can serve as generators to recharge the battery 195 in a regeneration mode. The electric power delivered from or to MGs 182 and 184 passes through the inverter 197 to the battery 195. The brake pedal sensor 188 can detect pressure applied to brake pedal 186, which may further affect the applied torque to wheels 170. The speed sensor 160 is connected to an output shaft of transmission 152 to detect a speed input which is converted into a vehicle speed by ECU 156. The accelerometer 162 is connected to the body of vehicle 100 to detect the actual deceleration of vehicle 100, which corresponds to a deceleration torque.

The transmission 152 may be a transmission suitable for any vehicle. For example, transmission 152 can be an electronically controlled continuously variable transmission (ECVT), which is coupled to engine 180 as well as to MGs 91 and 92. Transmission 20 can deliver torque output from a combination of engine 180 and MGs 91 and 92. The ECU 156 controls the transmission 152, utilizing data stored in memory 154 to determine the applied torque delivered to the wheels 170. For example, ECU 156 may determine that at a certain vehicle speed, engine 180 should provide a fraction of the applied torque to the wheels 170 while one or both of the MGs 182 and 184 provide most of the applied torque. The ECU 156 and transmission 152 can control an engine speed (NE) of engine 180 independently of the vehicle speed (V).

The ECU 156 may include circuitry to control the above aspects of vehicle operation. Additionally, the ECU 156 may include, for example, a microcomputer that includes a one or more processing units (e.g., microprocessors), memory storage (e.g., RAM, ROM, etc.), and I/O devices. The ECU 156 may execute instructions stored in memory to control one or more electrical systems or subsystems in the vehicle. Furthermore, the ECU 156 can include one or more electronic control units such as, for example, an electronic engine control module, a powertrain control module, a transmission control module, a suspension control module, a body control module, and so on. As a further example, electronic control units can be included to control systems and functions such as doors and door locking, lighting, human-machine interfaces, cruise control, telematics, braking systems (e.g., anti-lock braking system (ABS) or electronic stability control (ESC)), battery management systems, and so on. These various control units can be implemented using two or more separate electronic control units, or using a single electronic control unit.

The MGs 182 and 184 each may be a permanent magnet type synchronous motor including for example, a rotor with a permanent magnet embedded therein. The MGs 182 and 184 may each be driven by an inverter controlled by a control signal from ECU 156 so as to convert direct current (DC) power from the battery 195 to alternating current (AC) power, and supply the AC power to the MGs 182 and 184. In some examples, a first MG 182 may be driven by electric power generated by a second MG 184. It should be understood that in embodiments where MGs 182 and 184 are DC motors, no inverter is required. The inverter, in conjunction with a converter assembly may also accept power from one or more of the MGs 182 and 184 (e.g., during engine charging), convert this power from AC back to DC, and use this power to charge battery 195 (hence the name, motor generator). The ECU 156 may control the inverter, adjust driving current supplied to the first MG 182, and adjust the current received from the second MG 184 during regenerative coasting and braking.

The battery 195 may be implemented as one or more batteries or other power storage devices including, for example, lead-acid batteries, lithium ion, and nickel batteries, capacitive storage devices, and so on. The battery 195 may also be charged by one or more of the MGs 182 and 184, such as, for example, by regenerative braking or by coasting during which one or more of the MGs 182 and 184 operates as generator. Alternatively (or additionally, the battery 195 can be charged by the first MG 182, for example, when vehicle 100 is in idle (not moving/not in drive). Further still, the battery 195 may be charged by a battery charger (not shown) that receives energy from engine 180. The battery charger may be switched or otherwise controlled to engage/disengage it with battery 195. For example, an alternator or generator may be coupled directly or indirectly to a drive shaft of engine 180 to generate an electrical current as a result of the operation of engine 180. Still other embodiments contemplate the use of one or more additional motor generators to power the rear wheels of the vehicle 100 (e.g., in vehicles equipped with 4-Wheel Drive), or using two rear motor generators, each powering a rear wheel.

The battery 195 may also power other electrical or electronic systems in the vehicle 100. In some examples, the battery 195 can include, for example, one or more batteries, capacitive storage units, or other storage reservoirs suitable for storing electrical energy that can be used to power one or both of the MGs 182 and 184. When the battery 195 is implemented using one or more batteries, the batteries can include, for example, nickel metal hydride batteries, lithium ion batteries, lead acid batteries, nickel cadmium batteries, lithium ion polymer batteries, and other types of batteries.

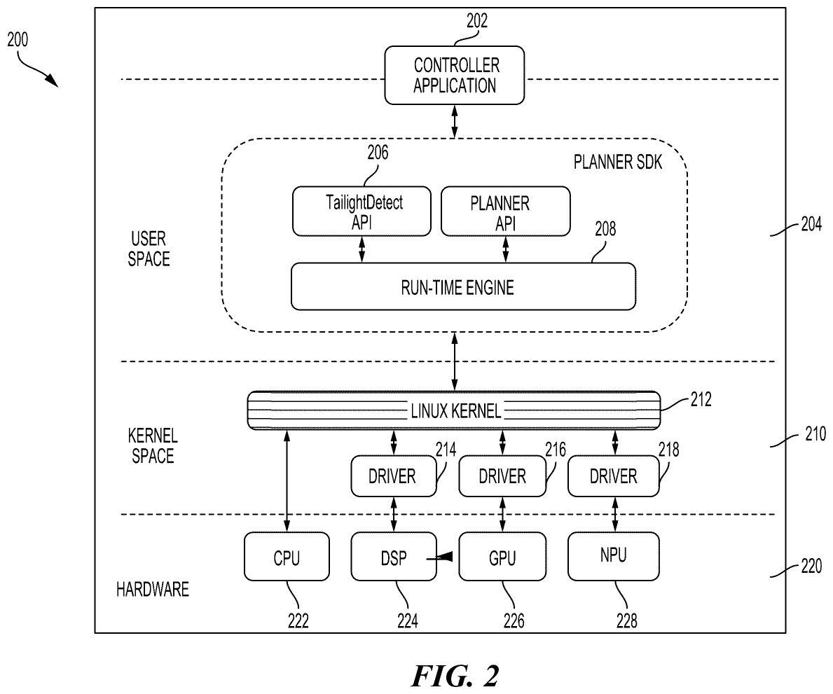

FIG. 2 is a block diagram illustrating a software architecture 200 that may visualize battery charging history of the vehicle 100, according to various aspects of the present disclosure. Using the architecture, a controller application 202 may be designed such that it may cause various processing blocks of a system-on-chip (SOC) 220 (for example a central processing unit (CPU) 222, a digital signal processor (DSP) 224, a graphics processing unit (GPU) 226 and/or an network processing unit (NPU) 228) to perform supporting computations during run-time operation of the controller application 202.

The controller application 202 may be configured to call functions defined in a user space 204 that may, for example, provide for visualizing battery charging history. The controller application 202 may make a request to compile program code associated with a library defined in a battery charging history visualization application programming interface (API) 206 to perform taillight recognition of an ado vehicle.

A run-time engine 208, which may be compiled code of a runtime framework, may be further accessible to the controller application 202. The controller application 202 may cause the run-time engine 208, for example, to take actions for visualizing battery charging history and/or monitoring charging activity. When charging activity is detected, the run-time engine 208 may in turn send a signal to an operating system 210, such as a Linux Kernel 212, running on the SOC 220. The operating system 210, in turn, may cause a computation to be performed on the CPU 222, the DSP 224, the GPU 226, the NPU 228, or some combination thereof. The CPU 222 may be accessed directly by the operating system 210, and other processing blocks may be accessed through a driver, such as drivers 214-218 for the DSP 224, for the GPU 226, or for the NPU 228. In the illustrated example, the deep neural network may be configured to run on a combination of processing blocks, such as the CPU 222 and the GPU 226, or may be run on the NPU 228, if present.

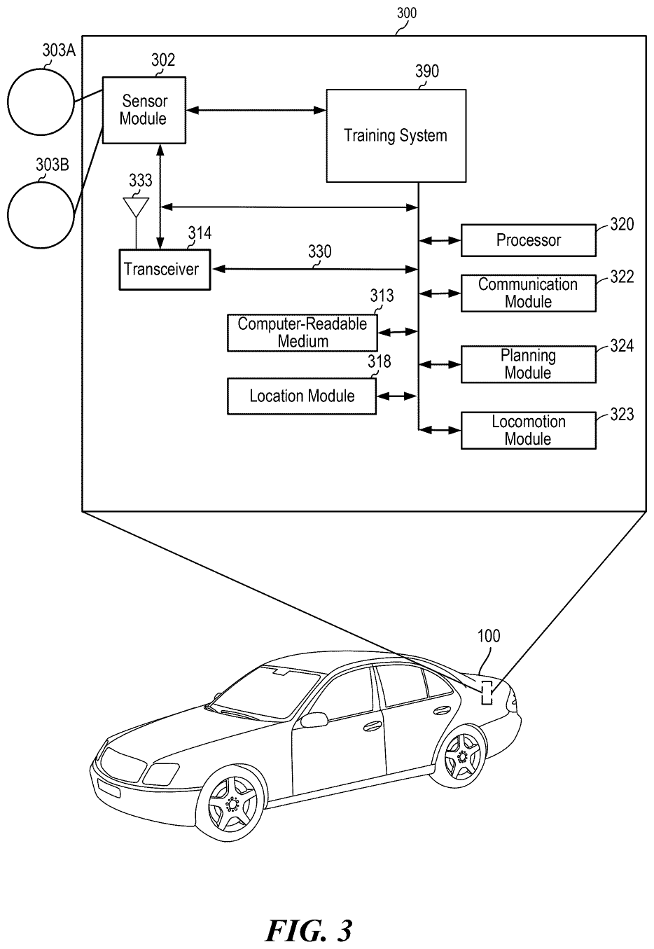

FIG. 3 is a diagram illustrating an example of a hardware implementation for a vehicle control system 300, according to aspects of the present disclosure. The vehicle control system 300 may be a component of a vehicle, a robotic device, or other device with one or more rechargeable batteries. For example, as shown in FIG. 3, the vehicle control system 300 is a component of a vehicle 100. Aspects of the present disclosure are not limited to the vehicle control system 300 being a component of the vehicle 100, as other devices, such as a bus, boat, drone, or robot, are also contemplated for using the vehicle control system 300. In the example of FIG. 3, the vehicle system may include a battery charging history visualization system 390. In some examples, battery charging history visualization system 390 is configured to perform operations, including operations of the process 500 described with reference to FIG. 5.

The vehicle control system 300 may be implemented with a bus architecture, represented generally by a bus 330. The bus 330 may include any number of interconnecting buses and bridges depending on the specific application of the vehicle control system 300 and the overall design constraints. The bus 330 links together various circuits including one or more processors and/or hardware modules, represented by a processor 320, a communication module 322, a location module 318, a sensor module 302, a locomotion module 323, a planning module 324, and a computer-readable medium 313. The bus 330 may also link various other circuits such as timing sources, peripherals, voltage regulators, and power management circuits, which are well known in the art, and therefore, will not be described any further.

The vehicle control system 300 includes a transceiver 314 coupled to the processor 320, the sensor module 302, a comfort module 308, the communication module 322, the location module 318, the locomotion module 323, the planning module 324, and the computer-readable medium 313. The transceiver 314 is coupled to an antenna 333. The transceiver 314 communicates with various other devices over a transmission medium. For example, the transceiver 314 may receive commands via transmissions from a user or a remote device. As another example, the transceiver 314 may transmit driving statistics and information from the comfort module 308 to a server (not shown).

In one or more arrangements, one or more of the modules 302, 313, 314, 318, 320, 322, 323, 324, 390, can include artificial or computational intelligence elements, such as, neural network, fuzzy logic or other machine learning algorithms. Further, in one or more arrangements, one or more of the modules 302, 313, 314, 318, 320, 322, 323, 324, 390 can be distributed among multiple modules 302, 313, 314, 318, 320, 322, 323, 324, 390 described herein. In one or more arrangements, two or more of the modules 302, 313, 314, 318, 320, 322, 323, 324, 390 of the vehicle control system 300 can be combined into a single module.

The vehicle control system 300 includes the processor 320 coupled to the computer-readable medium 313. The processor 320 performs processing, including the execution of software stored on the computer-readable medium 313 providing functionality according to the disclosure. The software, when executed by the processor 320, causes the vehicle control system 300 to perform the various functions described for a particular device, such as the vehicle 328, or any of the modules 302, 313, 314, 318, 320, 322, 323, 324, 390. The computer-readable medium 313 may also be used for storing data that is manipulated by the processor 320 when executing the software.

The sensor module 302 may be used to obtain measurements via different sensors, such as a first sensor 303A and a second sensor 303B. The first sensor 303A and/or the second sensor 303B may be a vision sensor, such as a stereoscopic camera or a red-green-blue (RGB) camera, for capturing 2D images. In some examples, one or both of the first sensor 303A or the second sensor 303B may be used to identify an intersection, a crosswalk, or another stopping location. Additionally, or alternatively, one or both of the first sensor 303A or the second sensor 303B may identify objects within a range of the vehicle 100. In some examples, one or both of the first sensor 303A or the second sensor 303B may identify a pedestrian or another object in a crosswalk. The first sensor 303A and the second sensor 303B are not limited to vision sensors as other types of sensors, such as, for example, light detection and ranging (LiDAR), a radio detection and ranging (radar), sonar, and/or lasers are also contemplated for either of the sensors 303A, 303B. The measurements of the first sensor 303A and the second sensor 303B may be processed by one or more of the processor 320, the sensor module 302, the comfort module 308, the communication module 322, the location module 318, the locomotion module 323, the planning module 324, in conjunction with the computer-readable medium 313 to implement the functionality described herein. In one configuration, the data captured by the first sensor 303A and the second sensor 303B may be transmitted to an external device via the transceiver 314. The first sensor 303A and the second sensor 303B may be coupled to the vehicle 328 or may be in communication with the vehicle 328.

Additionally, the sensor module 302 may configure the processor 320 to obtain or receive information from the one or more sensors 303A and 303B. The information may be in the form of one or more two-dimensional (2D) image(s) and may be stored in the computer-readable medium 313 as sensor data. In the case of 2D, the 2D image is, for example, an image from the one or more sensors 303A and 303B that encompasses a field-of-view about the vehicle 100 of at least a portion of the surrounding environment, sometimes referred to as a scene. That is, the image is, in one approach, generally limited to a subregion of the surrounding environment. As such, the image may be of a forward-facing (e.g., the direction of travel) 30, 90, 120-degree field-of-view (FOV), a rear/side facing FOV, or some other subregion as defined by the characteristics of the one or more sensors 303A and 303B. In further aspects, the one or more sensors 303A and 303B may be an array of two or more cameras that capture multiple images of the surrounding environment and stitch the images together to form a comprehensive 330-degree view of the surrounding environment. In other examples, the one or more images may be paired stereoscopic images captured from the one or more sensors 303A and 303B having stereoscopic capabilities.

The location module 318 may be used to determine a location of the vehicle 328. For example, the location module 318 may use a global positioning system (GPS) to determine the location of the vehicle 328. The communication module 322 may be used to facilitate communications via the transceiver 314. For example, the communication module 322 may be configured to provide communication capabilities via different wireless protocols, such as Wi-Fi, long term evolution (LTE), 3G, etc. The communication module 322 may also be used to communicate with other components of the vehicle 328 that are not modules of the vehicle control system 300. Additionally, or alternatively, the communication module 322 may be used to communicate with an occupant of the vehicle 100. Such communications may be facilitated via audio feedback from an audio system of the vehicle 100, visual feedback via a visual feedback system of the vehicle, and/or haptic feedback via a haptic feedback system of the vehicle.

The locomotion module 323 may be used to facilitate locomotion of the vehicle 328. As an example, the locomotion module 323 may control movement of the wheels. As another example, the locomotion module 323 may be in communication with a power source of the vehicle 328, such as an engine or batteries. Of course, aspects of the present disclosure are not limited to providing locomotion via wheels and are contemplated for other types of components for providing locomotion, such as propellers, treads, fins, and/or jet engines.

The vehicle control system 300 also includes the planning module 324 for planning a route or controlling the locomotion of the vehicle 328, via the locomotion module 323. A route may be planned to a passenger based on compartment data provided via the comfort module 308. In one configuration, the planning module 324 overrides the user input when the user input is expected (e.g., predicted) to cause a collision. The modules may be software modules running in the processor 320, resident/stored in the computer-readable medium 313, one or more hardware modules coupled to the processor 320, or some combination thereof.

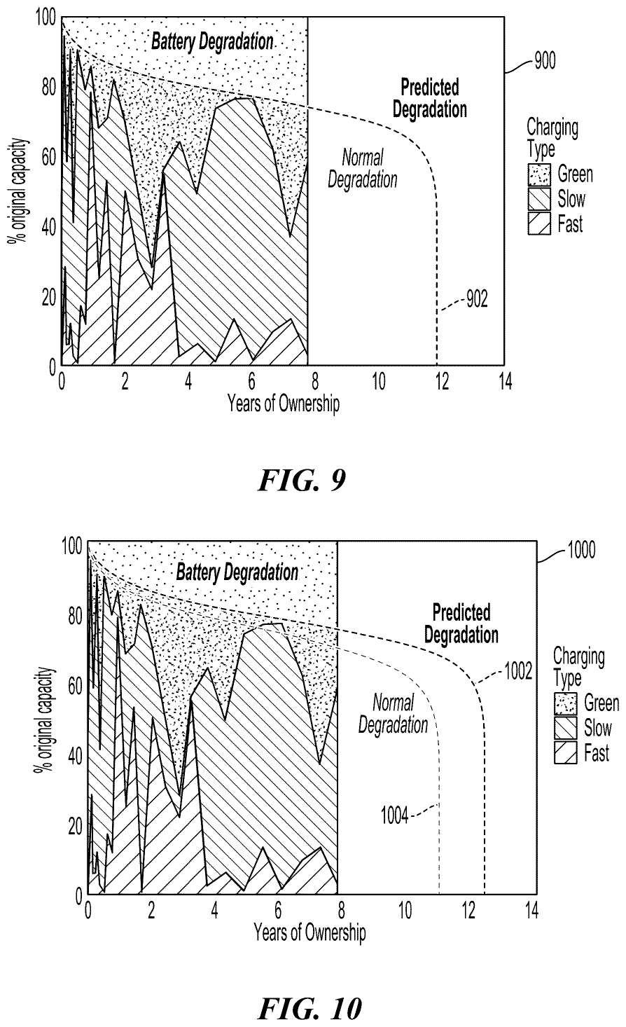

The battery charging history visualization system 390 may be in communication with the sensor module 302, the transceiver 314, the processor 320, the communication module 322, the location module 318, the locomotion module 323, the planning module 324, and the computer-readable medium 313. In some examples, the battery charging history visualization system 390 may be implemented as a machine learning model. Working in conjunction with one or more of the sensors 303A, 303B, the sensor module 302, and/or one or more other modules 313, 314, 318, 320, 322, 323, 324, the battery charging history visualization system 390 may perform one or more elements of the process 900 described with reference to FIG. 9.

Based on U.S. regulations, vehicles, such as EVs, may be mandated to display battery health information. These regulations specify that drivers should have access to an instant readout of the percent of mileage loss due to battery degradation. However, this approach has several potential drawbacks. Firstly, the percentage of battery degradation may not be easily understood by drivers, leaving drivers unclear about the health of their battery. Secondly, in most cases, the observed loss (approximately 2% per year) is a normal occurrence and not necessarily a cause for concern. Lastly, the percentage of mileage loss due to battery degradation does not provide drivers with insights into better charging behaviors or highlight the specific charging history that might have contributed to the battery's condition.

In some cases, smartphone devices or portable devices display a numerical percentage representing the remaining maximum battery capacity compared to the original capacity when the battery was new. However, these devices lack any visualization tools to illustrate charging habits or battery degradation over time. Additionally, displaying the numerical percentage representing the remaining maximum battery capacity compared to the original capacity presents other issues. For example, people tend to interpret numerical trends linearly, but battery degradation follows a non-linear pattern. Initially, degradation occurs rapidly, then slows and becomes linear during the mid-life of the battery, and finally, degradation sharpens again near the end-of-life. Cognitive psychology research has consistently demonstrated that people think linearly about increasing or decreasing numbers. This misunderstanding can lead to incorrect assumptions about battery health. For example, people might interpret rapid early degradation as an indicator of a shorter remaining lifespan for the battery or vehicle, while slow mid-life degradation might falsely suggest a steady decline until end-of-life, not accounting for the rapid degradation that occurs later. This phenomenon is similar to the “MPG Illusion,” where people mistakenly believe that each unit increase in miles per gallon results in equal increases in fuel efficiency, despite the logarithmic relationship.

Secondly, numerical percentages fail to provide a history of usage. A static numerical percentage only offers a snapshot of the current state of health of the battery without detailing the history of degradation or the conditions that caused increased or decreased degradation. Factors such as different types and speeds of charging impact battery health, but this information remains hidden in a simple percentage display.

To address these issues, various aspects of the present disclosure are directed to generating a visualization that presents a detailed history of different types of charging activities that can impact the battery's health over time. The visualization may be referred to as a battery flag. Furthermore, the visualization may provide a more comprehensive view of the battery's condition beyond the mere percentage of degradation. In some examples, the visualization illustrates overall charging habits and how these habits could lead to service issues or indicate that the battery has been well maintained. By displaying a normalized area chart, the visualization improves a user's understanding of their charging behaviors and how the charging behaviors affect battery health. The charging behavior may indicate a type of charger that was used, such as fast charging, level one (L1), or level two (L2). The charging behavior may also be referred to as a charging pattern. Providing a visualization of the charging behavior helps inform drivers of the best practices for maintaining battery health and allows drivers to make more informed decisions regarding their charging habits and overall vehicle maintenance.

In some examples, to generate the visualization, an EV may be equipped with systems that continuously monitor various parameters affecting battery health, including SoC, temperature, and charging behavior. Educating users about optimal charging practices and the impacts of different driving behaviors on battery health can help prolong battery life. Visual tools, such as battery flags, can help drivers understand their battery health better and make informed decisions about their vehicle usage. Battery health is a critical aspect of EV maintenance that affects performance, safety, and cost-efficiency. Providing a visualization to help drivers better understand and monitor the factors that influence battery health may increase the lifespan and efficiency of EV batteries.

In some examples, a normalized area chart displays the different types of charging over time. This chart does not indicate an amount of battery charged but focuses solely on the type of charge used. When calculating battery degradation, the system considers both the charge type and the duration of charging. For instance, two hours of fast charging causes more degradation than two hours of slow charging at 110 volts. A simple legend accompanies the chart, mapping the various charge types for easy interpretation. This normalized area chart helps users understand how different charging practices impact battery health over time, allowing users to make more informed decisions about their charging habits.

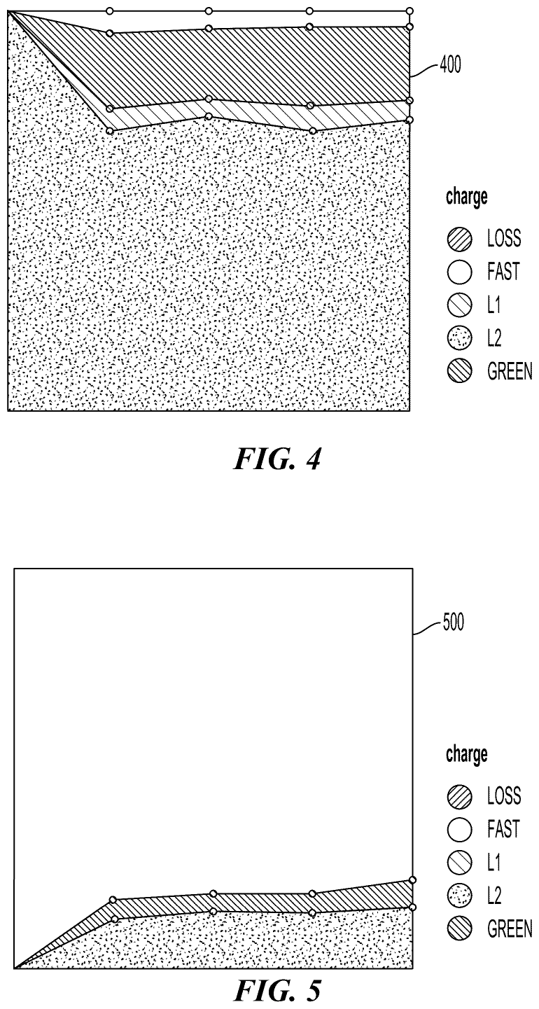

FIG. 4 is a diagram illustrating an example of a visualization 400, in accordance with various aspects of the present disclosure. The visualization 400 may use a color-coded legend (shown as different cross-hatching in the example of FIG. 4) to represent different charging types over time, including Loss, Fast, L1, L2, and Green. As shown in the visualization 400 of FIG. 4, a user predominantly used L2 charging. The X-axis represents time, and the Y-axis indicates the percentage of each charging type. The labeling of these axes is not necessary for understanding the flag and is considered optional. The visualization 400 shown in the example of FIG. 4 may help users identify their charging habits and understand the impact on battery health. The color-coded legend may provide for quick interpretation, making it clear which types of charging have been most frequently used over a given period.

FIG. 5 is a diagram illustrating an example of a visualization 500, in accordance with various aspects of the present disclosure. In the example of FIG. 5, the visualization 500 illustrates a charging pattern where the user predominantly employed fast charging in comparison to other types of charging, such as L1 and L2. Fast charging, while convenient, tends to degrade battery health more rapidly than slower charging methods. Therefore, a battery with a higher proportion of fast charging, as shown in the visualization 500, likely experiences more significant degradation over time compared to a battery charged predominantly with slower methods. Based on the visualizations 400 and 500 shown with respect to FIGS. 4 and 5, a user may quickly determine which battery was better maintained based on the charging habits displayed. Specifically, the visualizations 400 and 500 help users quickly assess the impact of their charging behaviors on battery health and encourages more balanced charging practices for better long-term battery maintenance.

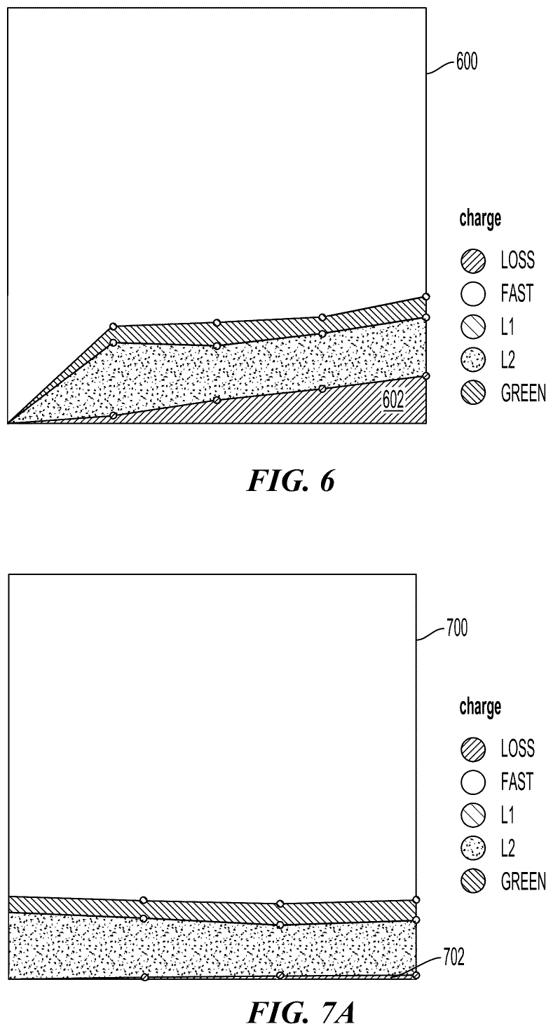

FIG. 6 is a diagram illustrating an example of a visualization 600, in accordance with various aspects of the present disclosure. In the example of FIG. 6, the visualization 600 displays a percentage of battery degradation 602 (labeled as loss in the example of FIG. 6). The percentage correlating to the battery degradation 602 may also correspond to a percentage displayed on a display unit of the vehicle indicating an amount of battery that remains at capacity. For example, a value of 90% indicates that 90% of the battery's capacity remains when the battery is fully charged. In this example, 10% of the battery capacity has been lost due to normal battery degradation and/or user charging history. The visualization 602 of battery degradation may potentially mislead owners into thinking that their actions are causing harm, even if the observed degradation is within expected norms. That is, most batteries follow an expected degradation over time. To avoid unnecessary concern and/or user confusion, in some examples, the degradation may only be displayed when advanced degradation occurs.

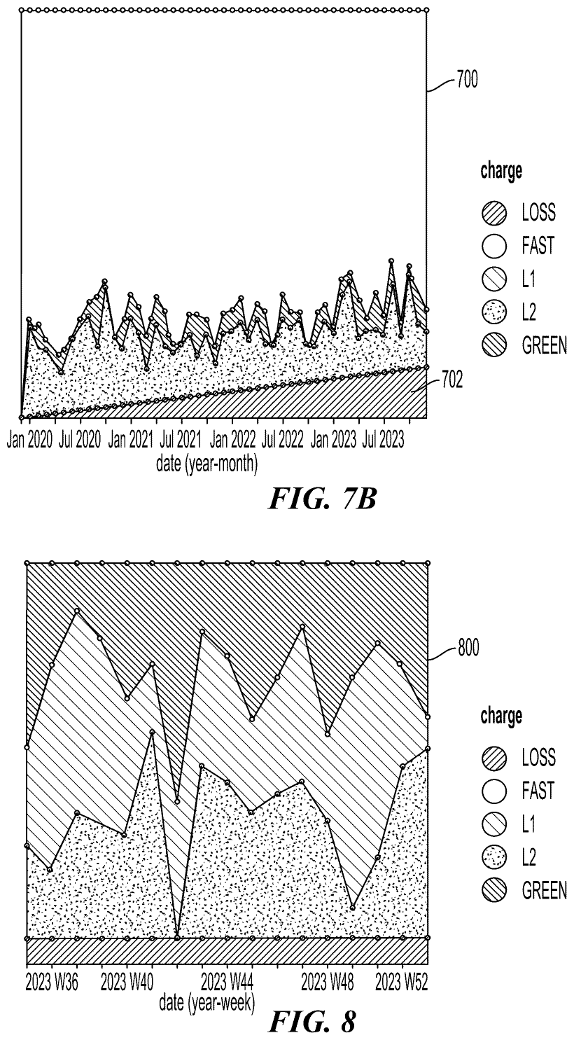

FIG. 7A is a diagram illustrating an example of a visualization 700, in accordance with various aspects of the present disclosure. In the example of FIG. 7, the visualization 700 displays a percentage of battery degradation 702 (labeled as “loss” in the example of FIG. 6) that is minimized to only account for advanced degradation. The advanced degradation may be battery degradation that results from a charging history. For example, in the example of FIG. 7A, the majority of the charging has been fast charging, which increases battery degradation over time.

By minimizing or exaggerating the degradation indication 702 as needed, the visualization can more accurately indicate significant battery health issues. As such, the user may be prompted to take corrective actions only when truly necessary. The visualization 700 also highlights the predominance of fast charging and its contribution to overall battery degradation, such that the user is provided with a clear and informative visualization of charging habits and their impact.

In some examples, a granularity of the battery health visualization may vary depending on the level of detail desired by a user. Different levels of granularity serve distinct purposes. A daily view provides the most detailed level, showing specific charging events each day, which helps understand daily habits and how particular days might contribute to battery degradation. A weekly view aggregates daily data into weekly patterns, making it easier to spot trends and outliers without the noise of daily fluctuations, thereby helping identify consistent charging habits or unusual weeks that deviate from the norm. A monthly view balances detail and trend visualization, helping users see broader patterns and the cumulative effect of their charging habits over longer periods. Quarterly or yearly views offer a high-level overview of trends over several months or a year, useful for long-term analysis and assessing the overall health and performance of the battery over significant timeframes. Daily and weekly views provide detailed insights that can help users make immediate adjustments to their charging habits and are useful for identifying specific behaviors that contribute to rapid battery degradation. In contrast, monthly, quarterly, and yearly views offer a broader perspective on long-term trends and the overall impact of charging habits. These views help users understand how their behaviors affect battery health over extended periods, allowing for strategic adjustments and planning.

FIG. 7B is an example of the visualization 700 with an adjusted granularity, in accordance with various aspects of the present disclosure. In the example of FIG. 7B, the visualization 700 is zoomed in to show a monthly view, offering a detailed look at the charging and degradation patterns over time (for example, June 2020 to July 2023). This level of granularity allows users to observe daily or weekly fluctuations in charging behaviors and their immediate impact on battery health. In the example of FIG. 7B, the visualization 700 shows frequent fast charging, and fewer L1 and L2 charging. The visualization 700 also shows cumulative battery degradation 702. This level of detail allows users to see how often they use fast charging and its impact on battery health over months. If the battery degradation 702 area increases significantly, users might recognize the need to reduce fast charging sessions to preserve battery life. By adjusting the granularity of the visualization, users can gain different insights into their charging habits and battery health, empowering them to make informed decisions that enhance the longevity and performance of their EV batteries.

As discussed, a user may adjust the visualization to show weekly or daily details. FIG. 8 is an example of the visualization 800 with an adjusted granularity, in accordance with various aspects of the present disclosure. In the example of FIG. 8, the visualization 800 shows charging information on a weekly basis. This advanced zoom level may provide a detailed history of charging types but may not offer the same at-a-glance health summary as the overall visualization, such as the visualizations 400, 500, 600, and 700 described with reference to FIGS. 4-7A. Therefore, while granular visualizations may provide in-depth analysis, the granular visualizations may be considered secondary to overall visualizations, which focus on delivering a clear and immediate overview of battery health.

In accordance with various aspects of the present disclosure, battery flags visualize the non-linear nature of battery degradation, showing how a battery's health changes over time in a manner that accounts for varying usage and/or charging patterns. These visualizations can also compare the degradation of a current battery or a potential purchase against expected rates of degradation for that specific vehicle model. For example, a battery flag can display the anticipated degradation of a consumer's vehicle, illustrating how battery health evolves over time while addressing cognitive biases that lead people to assume linear relationships.

FIG. 9 is a diagram illustrating an example of a visualization 900 showing a predicted degradation, in accordance with various aspects of the present disclosure. In the example of FIG. 9, the visualization 900 (e.g., battery flag) depicts battery degradation over the years of ownership, illustrating how different charging types influence battery degradation over time. The Y-axis shows the percentage of the battery's original capacity, while the X-axis represents the years of ownership. This visualization 900 demonstrates how various charging behaviors impact battery health and longevity.

As shown in the example of FIG. 9, at year zero, the battery operates at 100% of its original capacity. As time progresses, different charging practices lead to a decline in capacity. The graph may use distinct colors (shown as different cross hatches) to represent these charging types. Green charging is the most optimal, causing the least degradation, whereas fast charging may degrade the battery more rapidly. Green charging is a type of charging, such as L2 charging, where the power from the grid is from a clean energy source. The battery degradation represented at the top of the visualization 900 indicates the actual observed battery degradation over time, showing the capacity loss as the years advance. This battery degradation visually represents a tangible decline in battery health due to various charging practices as well as expected battery degradation. The visualization also shows a predicted rate of degradation 902 that is predicated based on the assumption that the battery will continue to be charged and used in the same manner. This prediction 902 may be generated using machine learning models trained on historical data specific to that vehicle model. In some examples, a normal degradation is also shown. In the example of FIG. 9, the normal degradation aligns with the predicted degradation 902, indicating that the actual observed degradation matches the expected rate.

Normal degradation refers to an expected and natural decline in a battery's capacity and performance over time due to regular use and inherent chemical processes. This normal degradation occurs even under optimal conditions and is a standard aspect of battery aging. Several factors influence normal degradation, including chemical reactions within the battery during charging and discharging, the number of charge and discharge cycles, temperature effects, and the passage of time. Chemical reactions cause wear and tear on the battery materials, leading to reduced capacity. Each battery has a limited number of cycles it can undergo before its capacity diminishes significantly. Extreme temperatures can accelerate degradation, but normal degradation assumes that the battery is kept within its optimal temperature range. Even without heavy use, a battery's capacity will decline over time due to the gradual breakdown of its internal chemical structure.

Normal degradation is predictable, allowing manufacturers and engineers to model and forecast the normal degradation, thereby, creating standard benchmarks for battery performance. In most cases, normal degradation is non-linear, with a rapid initial loss of capacity, a slower rate during the middle of the battery's lifespan, and an accelerated decline as the battery approaches the end of its useful life. This gradual and manageable degradation affects the battery's ability to hold a charge, resulting in shorter driving ranges for electric vehicles and less efficient energy storage. Deviations from the expected normal degradation may indicate that the battery has been subjected to conditions or usage patterns that accelerate wear and tear.

In the example of FIG. 9, the visualization 900 shows an initial decline in battery capacity, followed by a slower degradation phase, and finally, a sharper decline as the battery approaches the end of its useful life. This non-linear counters the common cognitive bias of assuming linear degradation. Additionally, by comparing actual and predicted degradation rates, the visualization 900 provides a visual tool for users to understand and anticipate battery health trends. These visualizations guide users in recognizing whether their battery's performance is within expected parameters or if adjustments to usage patterns may be necessary to optimize battery life.

FIG. 10 is a diagram illustrating an example of a visualization 1000 showing a predicted degradation, in accordance with various aspects of the present disclosure. In the example of FIG. 10, the visualization 1000 (e.g., battery flag) depicts battery degradation over the years of ownership, illustrating how different charging types influence battery degradation over time. The Y-axis shows the percentage of the battery's original capacity, while the X-axis represents the years of ownership. This visualization 1000 demonstrates how various charging behaviors impact battery health and longevity. The different charging types of the visualization 1000 are similar to those described for the visualization 900 described with reference to FIG. 9.

In the example of FIG. 10, the visualization 1000 includes the predicted rate of degradation 1002 if the battery continues to be charged and used in the same manner, using machine learning models based on historical data for that specific vehicle model. The normal rate of degradation 1004 may serve as a benchmark for comparison. As shown in the example of FIG. 10, the actual observed degradation 1002 is better than the normal predicted degradation 1004, indicating that the battery has retained more of its original capacity over time than typically expected. The presence of substantial green and slow charging and minimal fast charging likely contributes to the lower-than-expected degradation 1002.

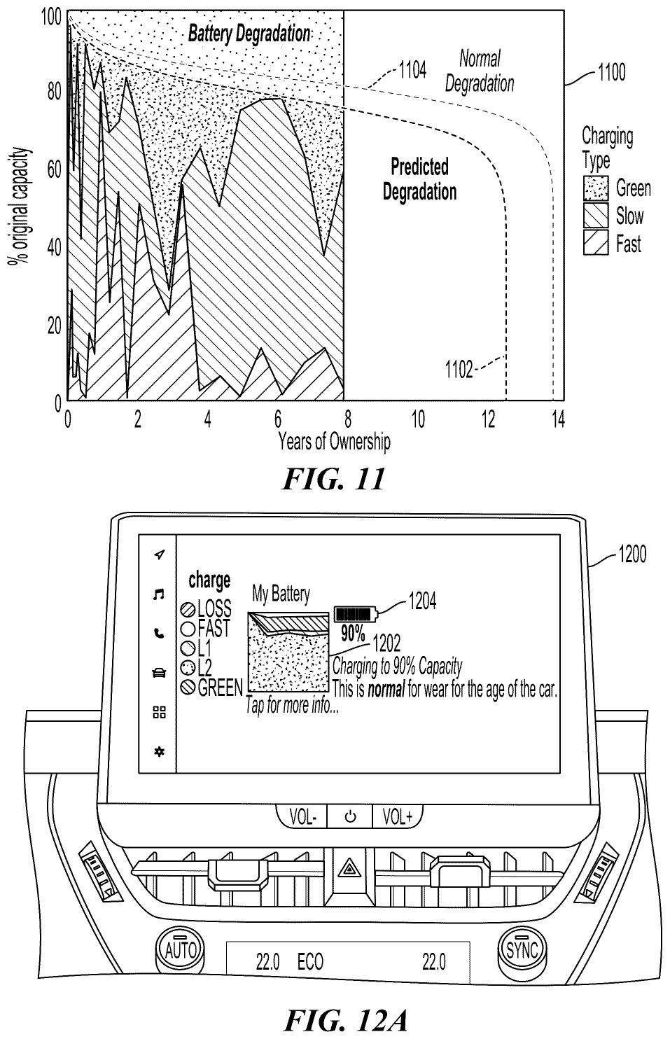

FIG. 11 is a diagram illustrating an example of a visualization 1100 showing a predicted degradation, in accordance with various aspects of the present disclosure. In the example of FIG. 11, the visualization 1100 (e.g., battery flag) depicts battery degradation over the years of ownership, illustrating how different charging types influence battery degradation over time. The Y-axis shows the percentage of the battery's original capacity, while the X-axis represents the years of ownership. This visualization 1100 demonstrates how various charging behaviors impact battery health and longevity. The different charging types of the visualization 1100 are similar to those described for the visualization 900 described with reference to FIG. 9.

In the example of FIG. 11, the visualization 1100 includes the predicted rate of degradation 1102 if the battery continues to be charged and used in the same manner, using machine learning models based on historical data for that specific vehicle model. The normal rate of degradation 1104 may serve as a benchmark for comparison. As shown in the example of FIG. 11, the actual observed degradation 1102 is worse than the normal predicted degradation 1104, indicating that the battery has lost more of its original capacity over time than typically expected. The presence of substantial fast charging over years one to four may contribute to the greater-than-expected degradation 1102.

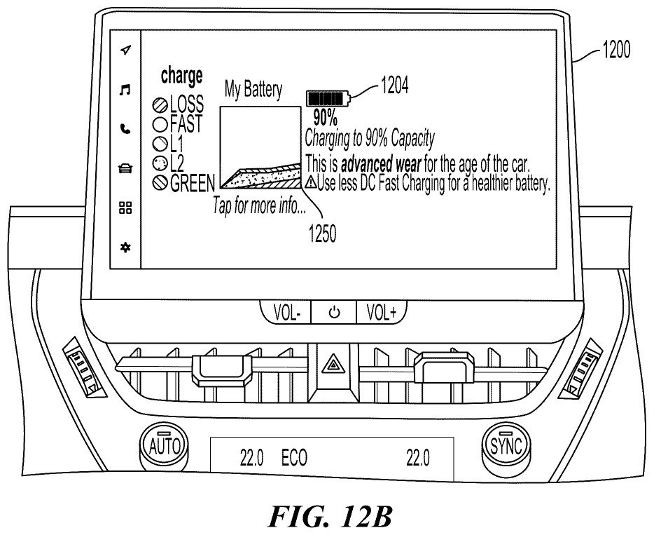

As discussed, the battery flag visualization, such as the visualizations 400, 500, 600, 700, 800, 900, 1000, and 1100 described with respect to FIGS. 1-6, 7A, 7B, and 8-11, respectively, may be displayed in an in-car display unit, such as a dashboard display unit or another type of display unit. FIG. 12A is a diagram illustrating an in-car display unit 1200 displaying a visualization 1202, in accordance with various aspects of the present disclosure. In the example of FIG. 12A, the visualization 1202 provides a visual representation of the battery's status and capacity (shown as 90%), along with relevant details about the charging and degradation history. The visualization 1202 may be color-coded to indicate different types of charging. Each type of charging and battery degradation may be represented by a different color.

A battery icon 1204 displays the current capacity at 90%, indicating the battery is charging to 90% of its original capacity. Below the battery icon, a status message reads, “Charging to 90% Capacity. This is normal for wear for the age of the car.” This message reassures the driver that the current battery capacity is within the expected range for the vehicle's age, suggesting that the battery is performing as anticipated. The message may also provide suggestions, if necessary, such as “use less fast charging.”That is, the message may provide guidance on increasing battery life. Additionally, a prompt “tap for more Info” may be provided so the user can access further details about the battery's health and charging history by interacting with the display.

Overall, the in-car display unit 1200 provides an at-a-glance overview of the battery's current health and charging status. The visualization 1202 allows the user (e.g., driver) to see how their charging habits have affected the battery over time. The capacity indicator 1204 and status message offer immediate feedback on the battery's condition, indicating that the battery's performance is normal and not a cause for concern. This type of display helps drivers understand and manage their battery health more effectively. By seeing both the current capacity and the historical charging data, drivers can make informed decisions about their charging practices. The reassurance that the battery's wear is normal for the car's age can help alleviate concerns about battery degradation, promoting a better overall experience for electric vehicle owners.

FIG. 12B is a diagram illustrating an in-car display unit 1200 displaying a visualization 1250, in accordance with various aspects of the present disclosure. In the example of FIG. 12A, the visualization 1250 provides a visual representation of the battery's status and capacity (shown as 90%), along with relevant details about the charging and degradation history. A status message beneath the icon 1204 reads, “Charging to 90% Capacity. This is advanced wear for the age of the car,” indicating that the battery's current state is associated with significant degradation relative to the vehicle's age. Additionally, the in-car display unit 1200 includes a warning message: “Use less DC Fast Charging for a healthier battery,” advising the driver to reduce the use of fast charging to mitigate further battery wear. The warning may be generated by a machine learning model that has been trained to generate a suggestion based on charging patterns, battery age, and/or type of vehicle.

As discussed, the way in which a user charges an electric vehicle (EV) impacts the long-term health of the EV's battery, similar to how mobile device's battery loses capacity over time. Frequently fast charging an EV battery can lead to accelerated degradation, doubling the wear rate compared to using slower, level two (L2) charging. Typically, L2 charging results in a degradation rate of approximately 2% per year, whereas constant fast charging can increase this rate to approximately 4% per year. This degradation affects not only the battery's performance but also the car's resale value and potential need for battery service. Fast charging over the vehicle's lifespan can lead to a degraded battery state.

To address this, various aspects of the present disclosure are directed to providing a visual representation of the battery's health and charging history. As an example, a visualization may show that a battery at 90% capacity, when fully charged, has predominantly undergone L2 charging, indicating a healthier battery. This visual representation is designed to be easily understandable at a glance, allowing users to quickly assess the state and history of their vehicle's battery.

Additionally, as discussed, battery degradation is inevitable, but it is not always a cause for alarm. In some examples, predicted degradation may be compared with normal degradation. This comparison helps contextualize the battery's state of health, showing whether it is degrading at a normal rate or better than expected under specific conditions. This prediction can be used to coach users on optimal charging practices, such as reducing fast charging in favor of slower or green charging methods.

Battery health may be predicted using heuristics or machine learning techniques, both aiming to estimate the remaining useful life of a battery and predict future degradation based on historical data and current usage patterns. Heuristic techniques may rely on predefined rules and formulas derived from empirical data and expert knowledge. For example, a simple rule might state that fast charging accelerates battery degradation by a certain percentage compared to slow charging. Linear degradation models assume a linear relationship between usage patterns and battery degradation, while look-up tables store historical degradation data for various conditions, allowing the system to predict battery health by matching current conditions to past data. Simplified functions based on physical and chemical processes can also predict battery life.

In contrast, machine learning techniques involve training models on historical battery data to predict future degradation. Supervised learning models, such as linear regression, decision trees, and support vector machines, learn from labeled training data to map input features like charge cycles and temperature to output labels like battery capacity. Deep learning models, such as neural networks, can capture complex, non-linear relationships between input features and battery health, with Recurrent Neural Networks (RNNs) and Long Short-Term Memory (LSTM) networks being particularly effective for time-series prediction tasks. Ensemble techniques, such as random forests or gradient boosting machines, may combine multiple models to improve prediction accuracy, while unsupervised learning techniques like clustering identify patterns and anomalies in battery usage data without labeled outcomes.

Accurate battery health prediction may rely on high-quality data, necessitating comprehensive data collection on charging cycles, environmental conditions, and/or usage patterns. Preprocessing steps, such as data cleaning, normalization, and feature extraction, enhance the quality and relevance of the data used for predictions. A system that continuously learns and updates its models with new data ensures that predictions remain accurate and relevant over time. Various aspects of the present disclosure may integrate heuristic techniques and/or machine learning techniques for a comprehensive and effective battery health prediction system that provides valuable insights and guidance for maintaining optimal battery performance.

Various aspects of the present disclosure provide historical explanations of the battery's health, predictions of future performance, and coaching on best practices. Battery degradation models, which are often sigmoidal in shape, show rapid initial degradation, a linear mid-life phase, and a sharp decline between 80% and 70% capacity. In some examples, models based on specific vehicle data can be developed. The visualization, which may be a stacked area chart aggregated by year, allows users to understand and interpret battery health at a glance, even without detailed scales. For instance, a person who has primarily used fast charging over the past three years would see significant battery degradation, represented by the red area at the bottom of the chart. Conversely, someone who has mostly used L2 charging would see less degradation. This simple and intuitive visualization helps users quickly assess and compare battery health over time, emphasizing the importance of optimal charging practices for maintaining battery longevity.

In some examples, coaching on best practices may include determining suggestions for improving battery health by analyzing data on battery usage and charging patterns to identify practices that can extend battery life and/or improve performance. These suggestions can be generated using heuristic techniques and/or machine learning techniques. Heuristic techniques may rely on predefined rules derived from expert knowledge and empirical data to guide the generation of suggestions. For instance, a rule might state that reducing the frequency of fast charging can improve battery longevity. Thresholds and limits can also be used, such as maintaining the battery's state of charge (SoC) within a specific range to reduce stress on the battery. Simple algorithms based on established battery management practices can offer straightforward recommendations, like avoiding extreme temperatures during charging and discharging.

Machine learning techniques, on the other hand, may involve analyzing historical data to recognize patterns associated with battery degradation. Predictive models can forecast future battery health based on current usage patterns and suggest alternative practices if significant degradation is predicted. Reinforcement learning functions can optimize battery management by learning from interactions with the environment, suggesting the most effective charging strategies based on results. A hybrid approach combining heuristic rules with machine learning insights can provide robust and reliable suggestions. For example, heuristic rules can offer quick, initial recommendations, while machine learning models refine these suggestions based on detailed data analysis.

Continuous data collection and real-time monitoring allow the system to adapt recommendations based on current conditions, such that suggestions are always relevant and up-to-date. Incorporating user feedback can further enhance the accuracy and relevance of the suggestions, allowing the system to learn and improve based on user input. Practical examples of suggestions include reducing fast charging to extend battery lifespan, keeping the battery charge between 20% and 80% for optimal health, avoiding charging in extreme temperatures, and adjusting charging times based on usage patterns. By integrating heuristic techniques, machine learning techniques, and continuous data monitoring, the system can generate accurate and actionable suggestions for improving battery health, helping users maintain their electric vehicle batteries in optimal condition.

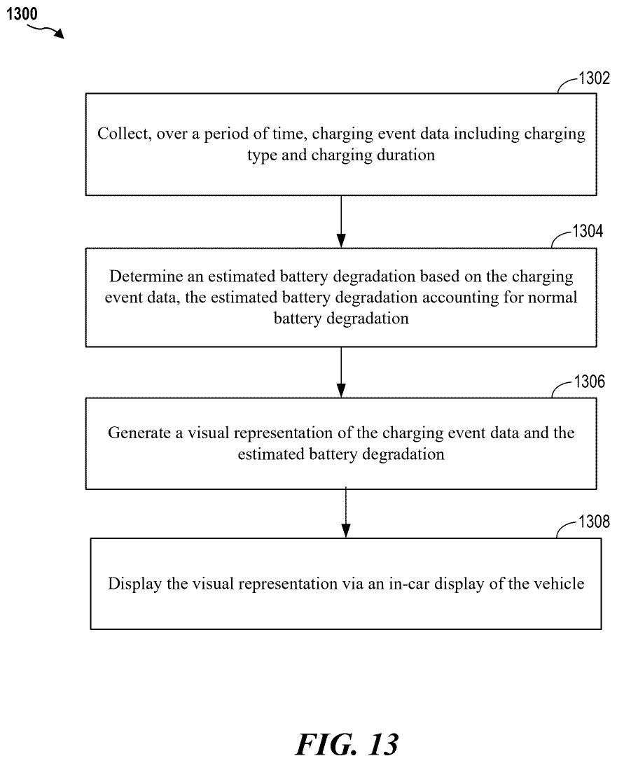

FIG. 13 is a diagram illustrating an example process 1300 for generating a visualization associated with battery health, in accordance with various aspects of the present disclosure. The process 1300 may be performed by a vehicle, such as a vehicle 100 as described with reference to FIGS. 1A 1B, 3, 7, 8A, and 8B/ As shown in the example of FIG. 13, the process 1300 begins at block 1302 by collecting, over a period of time, charging event data including charging type and charging duration. At block 1304, the process 1300 determines an estimated battery degradation based on the charging event data, the estimated battery degradation accounting for normal battery degradation. At block 1306, the process 1300 generates a visual representation of the charging event data and the estimated battery degradation. At block 1308, the process 1300 displays the visual representation via an in-car display of the vehicle. The visual representation may be a stacked area chart that uses color coding to differentiate between various charging types, including fast charging, level 1 (L1) charging, level 2 (L2) charging, and green charging. In some examples, the visual representation adjusts a total amount of battery degradation to remove degradation associated with the normal degradation.

In some examples, the process 1300 may also estimate future battery degradation based on historical charging event data, and display, via the visual representation, a comparison of future battery degradation to normal battery degradation. The future battery degradation may be estimated via a machine learning model trained on historical battery degradation data for a specific vehicle model associated with the re-chargeable battery. Additionally, or alternatively, in some examples, the process 1300 may determine one or more suggestions to extend battery lifespan, and display, via the in-car display, the one or more suggestions. Additionally, or alternatively, in some examples, the process 1300 may display, via the in-car display, a battery capacity indicator that indicates a current battery capacity as a percentage of the original capacity.

Based on the teachings, one skilled in the art should appreciate that the scope of the present disclosure is intended to cover any aspect of the present disclosure, whether implemented independently of or combined with any other aspect of the present disclosure. For example, an apparatus may be implemented or a method may be practiced using any number of the aspects set forth. In addition, the scope of the present disclosure is intended to cover such an apparatus or method practiced using other structure, functionality, or structure and functionality in addition to, or other than the various aspects of the present disclosure set forth. It should be understood that any aspect of the present disclosure may be embodied by one or more elements of a claim.

The word “exemplary” is used herein to mean “serving as an example, instance, or illustration.” Any aspect described herein as “exemplary” is not necessarily to be construed as preferred or advantageous over other aspects.

Although particular aspects are described herein, many variations and permutations of these aspects fall within the scope of the present disclosure. Although some benefits and advantages of the preferred aspects are mentioned, the scope of the present disclosure is not intended to be limited to particular benefits, uses or objectives. Rather, aspects of the present disclosure are intended to be broadly applicable to different technologies, system configurations, networks and protocols, some of which are illustrated by way of example in the figures and in the following description of the preferred aspects. The detailed description and drawings are merely illustrative of the present disclosure rather than limiting, the scope of the present disclosure being defined by the appended claims and equivalents thereof.

As used herein, the term “determining” encompasses a wide variety of actions. For example, “determining” may include calculating, computing, processing, deriving, investigating, looking up (e.g., looking up in a table, a database or another data structure), ascertaining and the like. Additionally, “determining” may include receiving (e.g., receiving information), accessing (e.g., accessing data in a memory) and the like. Furthermore, “determining” may include resolving, selecting, choosing, establishing, and the like.

As used herein, a phrase referring to “at least one of” a list of items refers to any combination of those items, including single members. As an example, “at least one of: a, b, or c”is intended to cover: a, b, c, a-b, a-c, b-c, and a-b-c.

The various illustrative logical blocks, modules and circuits described in connection with the present disclosure may be implemented or performed with a processor specially configured to perform the functions discussed in the present disclosure. The processor may be a neural network processor, a digital signal processor (DSP), an application specific integrated circuit (ASIC), a field programmable gate array signal (FPGA) or other programmable logic device (PLD), discrete gate or transistor logic, discrete hardware components or any combination thereof designed to perform the functions described herein. Alternatively, the processing system may comprise one or more neuromorphic processors for implementing the neuron models and models of neural systems described herein. The processor may be a microprocessor, controller, microcontroller, or state machine specially configured as described herein. A processor may also be implemented as a combination of computing devices, e.g., a combination of a DSP and a microprocessor, a plurality of microprocessors, one or more microprocessors in conjunction with a DSP core, or such other special configuration, as described herein.

The steps of a method or algorithm described in connection with the present disclosure may be embodied directly in hardware, in a software module executed by a processor, or in a combination of the two. A software module may reside in storage or machine readable medium, including random access memory (RAM), read only memory (ROM), flash memory, erasable programmable read-only memory (EPROM), electrically erasable programmable read-only memory (EEPROM), registers, a hard disk, a removable disk, a CD-ROM or other optical disk storage, magnetic disk storage or other magnetic storage devices, or any other medium that can be used to carry or store desired program code in the form of instructions or data structures and that can be accessed by a computer. A software module may comprise a single instruction, or many instructions, and may be distributed over several different code segments, among different programs, and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a device. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement signal processing functions. For certain aspects, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processor may be responsible for managing the bus and processing, including the execution of software stored on the machine-readable media. Software shall be construed to mean instructions, data, or any combination thereof, whether referred to as software, firmware, middleware, microcode, hardware description language, or otherwise.

In a hardware implementation, the machine-readable media may be part of the processing system separate from the processor. However, as those skilled in the art will readily appreciate, the machine-readable media, or any portion thereof, may be external to the processing system. By way of example, the machine-readable media may include a transmission line, a carrier wave modulated by data, and/or a computer product separate from the device, all which may be accessed by the processor through the bus interface. Alternatively, or in addition, the machine-readable media, or any portion thereof, may be integrated into the processor, such as the case may be with cache and/or specialized register files. Although the various components discussed may be described as having a specific location, such as a local component, they may also be configured in various ways, such as certain components being configured as part of a distributed computing system.

The machine-readable media may comprise a number of software modules. The software modules may include a transmission module and a receiving module. Each software module may reside in a single storage device or be distributed across multiple storage devices. By way of example, a software module may be loaded into RAM from a hard drive when a triggering event occurs. During execution of the software module, the one or more processors may load some of the instructions into cache to increase access speed. One or more cache lines may then be loaded into a special purpose register file for execution by the processor. When referring to the functionality of a software module below, it will be understood that such functionality is implemented by the one or more processors when executing instructions from that software module. Furthermore, it should be appreciated that aspects of the present disclosure result in improvements to the functioning of the one or more processors, computer, machine, or other system implementing such aspects.

If implemented in software, the functions may be stored or transmitted over as one or more instructions or code on a computer-readable medium. Computer-readable media include both computer storage media and communication media including any storage medium that facilitates transfer of a computer program from one place to another.

Further, it should be appreciated that modules and/or other appropriate means for performing the methods and techniques described herein can be downloaded and/or otherwise obtained by a user terminal and/or base station as applicable. For example, such a device can be coupled to a server to facilitate the transfer of means for performing the methods described herein. Alternatively, various methods described herein can be provided via storage means, such that a user terminal and/or base station can obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. A method for visualizing health of a re-chargeable battery associated with a vehicle, comprising:
collecting, over a period of time, charging event data including charging type and charging duration;
determining an estimated battery degradation based on the charging event data, the estimated battery degradation accounting for normal battery degradation;
generating a visual representation of the charging event data and the estimated battery degradation; and
displaying the visual representation via an in-car display of the vehicle.

2. The method of claim 1, further comprising:
estimating future battery degradation based on historical charging event data; and
displaying, via the visual representation, a comparison of future battery degradation to normal battery degradation.

3. The method of claim 2, wherein the future battery degradation is estimated via a machine learning model trained on historical battery degradation data for a specific vehicle model associated with the re-chargeable battery.

4. The method of claim 1, further comprising:
determining one or more suggestions to extend battery lifespan; and
displaying, via the in-car display, the one or more suggestions.

5. The method of claim 1, wherein the visual representation is a stacked area chart that uses color coding to differentiate between various charging types, including fast charging, level 1 charging, level 2 charging, and green charging.

6. The method of claim 1, further comprising displaying, via the in-car display, a battery capacity indicator that indicates a current battery capacity as a percentage of the original capacity.

7. The method of claim 1, wherein the visual representation adjusts a total amount of battery degradation to remove degradation associated with the normal degradation.

8. An apparatus for visualizing health of a re-chargeable battery associated with a vehicle, comprising:
one or more processors; and
one or more memories coupled with the one or more processors and storing processor-executable code that, when executed by the one or more processors, is configured to cause the apparatus to:
collect, over a period of time, charging event data including charging type and charging duration;
determine an estimated battery degradation based on the charging event data, the estimated battery degradation accounting for normal battery degradation;
generate a visual representation of the charging event data and the estimated battery degradation; and
display the visual representation via an in-car display of the vehicle.

9. The apparatus of claim 8, wherein execution of the processor-executable code further causes the apparatus to:
estimate future battery degradation based on historical charging event data; and
display, via the visual representation, a comparison of future battery degradation to normal battery degradation.

10. The apparatus of claim 9, wherein the future battery degradation is estimated via a machine learning model trained on historical battery degradation data for a specific vehicle model associated with the re-chargeable battery.

11. The apparatus of claim 8, wherein execution of the processor-executable code further causes the apparatus to:
determine one or more suggestions to extend battery lifespan; and
display, via the in-car display, the one or more suggestions.

12. The apparatus of claim 8, wherein the visual representation is a stacked area chart that uses color coding to differentiate between various charging types, including fast charging, level 1 charging, level 2 charging, and green charging.

13. The apparatus of claim 8, wherein execution of the processor-executable code further causes the apparatus to display, via the in-car display, a battery capacity indicator that indicates a current battery capacity as a percentage of the original capacity.

14. The apparatus of claim 8, wherein the visual representation adjusts a total amount of battery degradation to remove degradation associated with the normal degradation.

15. A non-transitory computer-readable medium having program code recorded thereon for visualizing health of a re-chargeable battery associated with a vehicle, the program code executed by one or more processors and comprising:
program code to collect, over a period of time, charging event data including charging type and charging duration;
program code to determine an estimated battery degradation based on the charging event data, the estimated battery degradation accounting for normal battery degradation;
program code to generate a visual representation of the charging event data and the estimated battery degradation; and
program code to display the visual representation via an in-car display of the vehicle.

16. The non-transitory computer-readable medium of claim 15, wherein the program code further comprises:
program code to estimate future battery degradation based on historical charging event data; and
program code to display, via the visual representation, a comparison of future battery degradation to normal battery degradation.

17. The non-transitory computer-readable medium of claim 16, wherein the future battery degradation is estimated via a machine learning model trained on historical battery degradation data for a specific vehicle model associated with the re-chargeable battery.

18. The non-transitory computer-readable medium of claim 15, wherein the program code further comprises:
program code to determine one or more suggestions to extend battery lifespan; and
program code to display, via the in-car display, the one or more suggestions.

19. The non-transitory computer-readable medium of claim 15, wherein the visual representation is a stacked area chart that uses color coding to differentiate between various charging types, including fast charging, level 1 charging, level 2 charging, and green charging.

20. The non-transitory computer-readable medium of claim 15, wherein the program code further comprises program code to display, via the in-car display, a battery capacity indicator that indicates a current battery capacity as a percentage of the original capacity.
